(19) United States
(12) Patent Application Publication
(10) Pub. No.: US 2025/0140750 A1
(43) Pub. Date: May 1, 2025

(54) MEMORY DEVICE

(71) Applicant: Powerchip Semiconductor Manufacturing Corporation, Hsinchu (TW)

(72) Inventors: Chun-Lin Lu, Hsinchu City (TW); Chien-Ting Ho, Hsinchu (TW); Shou-Zen Chang, Hsinchu City (TW)

(73) Assignee: Powerchip Semiconductor Manufacturing Corporation, Hsinchu (TW)

(21) Appl. No.: 18/536,230

(22) Filed: Dec. 12, 2023

(30) Foreign Application Priority Data
Oct. 27, 2023 (TW) 112141299

(51) Int. Cl. H01L 25/065; H01L 23/00; H01L 23/522; H10B 80/00

(52) U.S. Cl. CPC H01L 25/0657; H01L 23/5226; H01L 24/08; H10B 80/00; H01L 2224/08145

(57) ABSTRACT

The present disclosure provides a memory device including a substrate including a first and a second surfaces opposite to each other, a first interconnection structure disposed on the first surface of the substrate, a first and second elements disposed in the substrate and/or the first interconnection structure, a second interconnection structure disposed on the first interconnection structure, and a third interconnection structure disposed on the second surface of the substrate. The first interconnection structure includes first wiring layers configured to be closest to the first and second elements. The third interconnection structure includes second wiring layers configured to be closest to the first and second elements. Each of the first and second elements includes a first electrical connection path through the first wiring layer and a second electrical connection path through the second wiring layer.

### CROSS-REFERENCE TO RELATED APPLICATION

This application claims the priority benefit of Taiwan application serial no. 112141299, filed on Oct. 27, 2023. The entirety of the above-mentioned patent application is hereby incorporated by reference herein and made a part of this specification.

### BACKGROUND

### Technical Field

The present invention is related to a semiconductor device, and more particular to a memory device.

### Description of Related Art

As the size of electronic devices continues to shrink and the user's requirements for the performance of the electronic devices continue to increase, a person having ordinary skilled in the art is striving for making the electronic devices include more components while maintaining the existing horizontal area, or maintaining the number of the existing components while having a minimized horizontal area. However, either of the above situations will significantly increase the density of interconnections (especially the density of interconnections closest to the components), which will require finer line widths.

In the current manufacturing processes, an extreme ultraviolet (EUV) with a small exposure wavelength is often used as the light source of the exposure machine, as such the interconnections with small line widths can be realized by narrowing the wavelength of the exposure light source. However, the lithography process with the EUV is expensive and energy-consuming, and in the case where the size of the electronic devices continues to shrink, the lithography process with EUV will still be unable to satisfy the desired size at that time. Accordingly, a person having ordinary skilled in the art continues to find the ways other than narrowing down the wavelength of the exposure light source.

### SUMMARY

The present invention provides a memory device in which a third interconnection structure including second wiring layers is disposed on the rear side of the substrate, so that a first element and a second element not only include a first electrical connection path through the first wiring layers on the front side of the substrate but also include a second electrical connection path through the second wiring layers on the rear side of the substrate. Namely, some of wirings in the wiring region on the front side of the wafer are moved to the rear side of the wafer, so the density of interconnections formed on the front side of the wafer can be reduced significantly. As such, the memory device is capable of including more components while maintaining the existing horizontal area and the design rule for the memory device can be relaxed as well, that is, the design with finer widths of the interconnections turns to be optional.

An embodiment of the invention provides a memory device including a substrate, a first interconnection structure, a first and a second elements, a second interconnection structure, and a third interconnection structure. The substrate includes a first surface and a second surface opposite to each other. The first interconnection structure is disposed on the first surface of the substrate. The first element and the second element are disposed in the substrate and/or the first interconnection structure, wherein the first interconnection structure includes a plurality of first wiring layers configured to be closest to the first and second elements. The second interconnection structure is disposed on the first interconnection structure. The third interconnection structure is disposed on the second surface of the substrate and includes a plurality of second wiring layers configured to be closest to the first and second elements. Each of the first element and the second element includes a first electrical connection path through the first wiring layers and a second electrical connection path through the second wiring layers.

In an embodiment of the invention, the substrate includes a cell region and a peripheral region adjacent to the cell region, and at least one of the first element and the second element is disposed in the peripheral region and is electrically connected to a memory array in the cell region through the first electrical connection path and/or the second electrical connection path.

In an embodiment of the invention, at least one of the first element and the second element includes a sense amplifier or a word line driver.

In an embodiment of the invention, the first element is connected to the second element through the first electrical connection path and/or the second electrical connection path.

In an embodiment of the invention, the third interconnection structure includes a first via penetrating the substrate and contacting the first element or the second element.

In an embodiment of the invention, the third interconnection structure includes a second via penetrating the substrate and the first interconnection structure and contacting the first wiring layer.

An embodiment of the invention provides a memory device including a first wafer and a second wafer stacked on the first wafer. The first wafer includes a first substrate, a first front interconnection structure, a plurality of first elements, a second front interconnection structure, and a first rear interconnection structure. The first substrate includes a front surface and a rear surface opposite to each other. The first front interconnection structure is disposed on the front surface of the first substrate. The first elements are disposed in the first substrate and/or the first front interconnection structure, wherein the first front interconnection structure includes a plurality of first wiring layers configured to be closest to the first elements. The second front interconnection structure is disposed on the first front interconnection structure. The first rear interconnection structure is disposed on the rear surface of the first substrate and includes a plurality of second wiring layers configured to be closest to the first elements. Each of the first elements includes a first front electrical connection path through the first wiring layers and a first rear electrical connection path through the second wiring layers. The second wafer includes a second substrate, a third front interconnection structure, a plurality of second elements, a fourth front interconnection structure, and a second rear interconnection structure. The second substrate is disposed on the second front interconnection structure and includes a front surface and a rear surface opposite to each other. The third front interconnection structure is disposed on the front surface of the second substrate. The second elements are disposed in the second substrate and/or the third front interconnection structure, wherein the third front interconnection structure includes a plurality of third wiring layers configured to be closest to the second elements. The fourth front interconnection structure is disposed on the third front interconnection structure. The second rear interconnection structure is disposed on the rear surface of the second substrate and includes a plurality of fourth wiring layers configured to be closest to the second elements. Each of the second elements includes a second front electrical connection path through the third wiring layers and a second rear electrical connection path through the fourth wiring layers. The second front interconnection structure includes a redistribution layer connecting the second rear electrical connection path.

In an embodiment of the invention, the redistribution layer is connected to the first front electrical connection path.

In an embodiment of the invention, the first rear interconnection structure and the second rear interconnection structure include first vias respectively penetrating the first substrate and the second substrate and respectively contacting the first elements and the second elements.

In an embodiment of the invention, each of the first rear interconnection structure and the second rear interconnection structure comprises second vias, the second vias of the first rear interconnection structure penetrate the first substrate and the first front interconnection structure and contact the first wiring layers, and the second vias of the second rear interconnection structure penetrate the second substrate and the third front interconnection structure and contact the third wiring layers.

In an embodiment of the invention, the second front interconnection structure includes front pads in direct contact with the fourth wiring layers.

In an embodiment of the invention, the second wafer includes through vias penetrating through the third front interconnection structure, the second substrate, and the second rear interconnection structure and contacting one of the fourth wiring layers.

Based on the above, in the aforementioned memory device, the third interconnection structure including the second wiring layers is disposed on the rear side of the substrate, so that the first and the second elements not only include a first electrical connection path (through the first wiring layers) on the front side of the substrate but also include a second electrical connection path (through the second wiring layers) on the rear side of the substrate. Namely, some of wirings originally disposed in the wiring region on the front side of the wafer are moved to the rear side of the wafer, so the density of interconnections formed on the front side of the wafer can be reduced significantly. As such, in the case where the memory device retains the existing horizontal area, the memory device is capable of achieving the design with more components by using the relaxed design rule (e.g., the design including interconnections with high density and fine line widths are optional but not necessary).

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-section view illustrating a memory device of an embodiment of the invention.

FIG. 2 is a schematic cross-section view illustrating a memory device of another embodiment of the invention.

FIG. 3 is a schematic cross-section view illustrating a wafer 10a shown in FIG. 2 of an embodiment of the invention.

FIG. 4 is a schematic cross-section view illustrating a wafer 10b shown in FIG. 2 of an embodiment of the invention.

FIG. 5 is a schematic cross-section view illustrating a wafer 10c shown in FIG. 2 of an embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

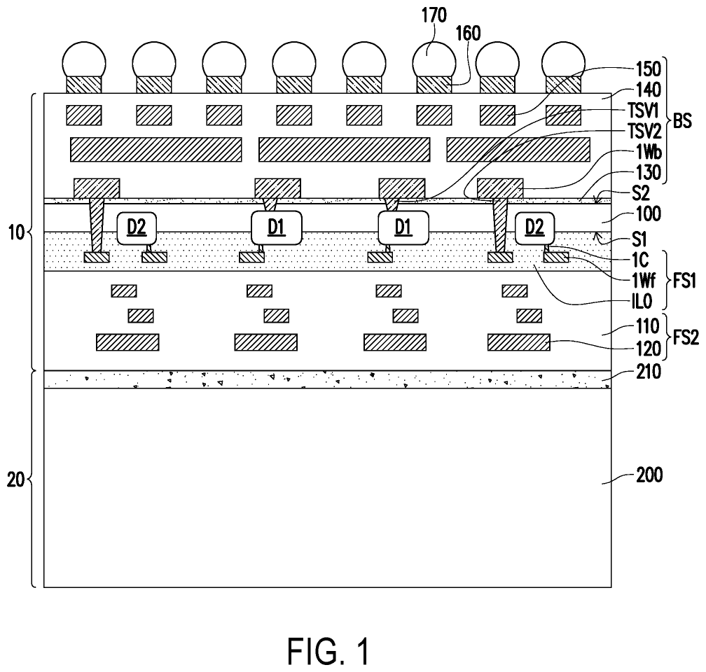

FIG. 1 is a schematic cross-section view illustrating a memory device of an embodiment of the invention.

Referring to FIG. 1, the memory device includes a wafer 10 and a carrier substrate 20 carrying the wafer 10. The wafer 10 includes a substrate 100, a first interconnection structure FS1, a first element D1 and a second element D2, a second interconnection structure FS2, and a third interconnection structure BS. The carrier substrate 20 may include a base substrate 200 and a bonding layer 210 formed on the base substrate 200. The base substrate 200 may include materials suitable for the substrate of the wafer, such as silicon. The bonding layer 210 may include materials suitable for the adhesive layer. The memory device may include a dynamic random-access memory (DRAM).

The substrate 100 includes a first surface S1 and a second surface S2 opposite to each other. The substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AIP, AlAs, InN, InP, InAs, GaNP, GaNAs, GaPAs, AlNP, AlNAs, AlPAs, InNP, InNAs, InPAs, GaAINP, GaAINAs, GaAlPAs, GaInNP, GaInNAs, GaInPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be n-type, whereas the second conductivity type may be p-type.

The first interconnection structure FS1 is disposed on the first surface S1 of the substrate 100. The first element D1 and the second element D2 are disposed in the substrate 100 and/or the first interconnection structure FS1. For example, at least one of the first element D1 and the second element D2 may include a well (not shown) formed in the substrate 100 and/or a structure (not shown) formed on the substrate 100 (i.e., being formed in the first interconnection structure FS1). In some embodiments, at least one of the first element D1 and the second element D2 may include a sense amplifier or a word line driver.

The first interconnection structure FS1 includes a plurality of first wiring layers 1Wf configured to be closest to the first element D1 and the second element D2. The first wiring layers 1Wf may include conductive materials such as metals or metal alloys. The metals and the metal alloys may be, for example, Cu, Al, Ti, Ta, W, Pt, Cr, Mo, or alloys thereof. In some embodiments, the first interconnection structure FS1 may include a dielectric layer ILO formed on the first surface S1 of the substrate 100 and where the first wiring layers 1Wf are formed therein and conductive contacts 1C formed in the dielectric layer ILO and electrically connected the first element D1 and the second element D2 to the first wiring layers 1Wf. The dielectric layer ILO may include a dielectric material such an oxide (e.g., silicon oxide) or a nitride (e.g., silicon nitride). The conductive contacts 1C may include conductive materials such as metals or metal alloys. The metals and the metal alloys may be, for example, Cu, Al, Ti, Ta, W, Pt, Cr, Mo, or alloys thereof.

The second interconnection structure FS2 is disposed on the first interconnection structure FS1. The second interconnection structure FS2 is electrically connected to the first interconnection structure FS1. In some embodiments, the second interconnection structure FS2 is disposed between the first interconnection structure FS1 and the bonding layer 210 of the carrier substrate 20. That is, in some embodiments, the wafer 10 may be flipped and placed on the carrier substrate 20 after the first interconnection structure FS1, the first element D1 and second element D2, and the second interconnection structure FS2 of the wafer 10 are formed. Then, after the thinning process is performed on the rear side of the wafer 10, the third interconnection structure BS is formed on the second surface S2 of the thinned substrate 100.

In some embodiments, the second interconnection structure FS2 may include a dielectric layer 110 and interconnections 120 formed in the dielectric layer 110. The dielectric layer 110 may include a single dielectric layer or multiple dielectric layers, but the invention is not limited thereto. The dielectric layer 110 may include a dielectric material such an oxide (e.g., silicon oxide) or a nitride (e.g., silicon nitride). The interconnections 120 may include a single wiring layer or multiple wiring layers or redistribution layers and vias connecting the wiring layers or the redistribution layers. The interconnections 120 may include conductive materials such as metals or metal alloys. The metals and the metal alloys may be, for example, Cu, Al, Ti, Ta, W, Pt, Cr, Mo, or alloys thereof.

The third interconnection structure BS is disposed on the second surface S2 of the substrate 100 and includes a plurality of second wiring layers 1Wb configured to be closest to the first element D1 and the second element D2, such that each of the first element D1 and the second element D2 includes a first electrical connection path through the first wiring layers 1Wf and a second electrical connection path through the second wiring layers 1Wb. In other words, some of wirings originally disposed in the wiring region on the front side of the wafer 10 are moved to the rear side of the wafer 10, so the density of interconnections (e.g., the density of the first wiring layers 1Wf) formed on the front side of the wafer 10 can be reduced significantly. As such, in the case where the memory device retains the existing horizontal area, the memory device is capable of achieving the design with more components by using the relaxed design rule, or in the case where the memory device retains the number of the existing components, the memory device is capable of achieving the design with the smaller horizontal area by using the relaxed design rule. It is worth noting that the wiring layers closer to the first element D1 and the second element D2 have a higher density and a finer line width, so in the case where some of the wiring layers closest to the first element D1 and second element D2 are moved from the front side of the wafer 10 to the rear side of the wafer 10, the design rule can be relaxed significantly.

In some embodiments, in the case where some of wiring layers are moved to the rear side of the wafer 10, the first element D1 may be connected to the second element D2 through the first electrical connection path (e.g., through the path of the first wiring layers 1Wf) and/or the second electrical connection path (e.g., through the path of the second wiring layers 1Wb). In some embodiments, the substrate 100 may include a cell region and a peripheral region adjacent to the cell region, wherein at least one of the first element D1 and the second element D2 may be disposed in the peripheral region and may be electrically connected to a memory array (not shown) in the cell region through the first electrical connection path (e.g., through the path through the first wiring layers 1Wf) and/or the second electrical connection path (e.g., through the second wiring layers 1Wb).

The third interconnection structure BS may include a dielectric layer 130 formed on the second surface S2 of the substrate 100 and vias (e.g., first vias TSV1 and second vias TSV2) electrically connecting the second wiring layers 1Wb to the first element D1 and/or the second element D2. For example, in some embodiments, the third interconnection structure BS may include first vias TSV1 penetrating the dielectric layer 130 and the substrate 100 and contacting the first element D1. In some embodiments, the third interconnection structure BS may include second vias TSV2 penetrating the dielectric layer 130, the substrate 100, and the first interconnection structure FS1 and contacting the first wiring layers 1Wf. The dielectric layer 130 may include a dielectric material such an oxide (e.g., silicon oxide) or a nitride (e.g., silicon nitride). The first vias TSV1 and/or the second vias TSV2 may include conductive materials such as metals, metal alloys, metal nitrides, metal silicides, or combinations thereof. In some embodiments, metals and metal alloys may be, for example, Cu, Al, Ti, Ta, W, Pt, Cr, Mo, or alloys thereof. The metal nitrides may be, for example, TiN, WN, TaN, TaSiN, TiSiN, WSiN, or combinations thereof. The metal silicides may include tungsten silicide, titanium silicide, cobalt silicide, zirconium silicide, platinum silicide, molybdenum silicide, copper silicide, nickel silicide, or combinations thereof.

The third interconnection structure BS may include dielectric layer 140 formed on the dielectric layer 130 and covering the second wiring layers 1Wb and interconnections 150 formed in the dielectric layer 140. The dielectric layer 140 may include a single dielectric layer or multiple dielectric layers, but the invention is not limited thereto. The dielectric layer 140 may include a dielectric material such an oxide (e.g., silicon oxide) or a nitride (e.g., silicon nitride). The interconnections 150 may include a single wiring layer or multiple wiring layers or redistribution layers and vias connecting the wiring layers or the redistribution layers. The interconnections 150 may include conductive materials such as metals or metal alloys. The metals and the metal alloys may be, for example, Cu, Al, Ti, Ta, W, Pt, Cr, Mo, or alloys thereof.

The memory device may include under-bump metallization (UBM) layers 160 formed on the third interconnection structure BS and electrical connection metals 170 formed on the UBM layers 160. In some embodiments, the wafer 10 may be physically connected and/or electrically connected to the external devices through the UBM layers 160 and the electrical connection metals 170. The UBM layers 160 may be formed by known metallization methods that use known conductive materials such as metals. The electrical connection metals 170 may include metals with low melting point, such as solders (e.g., Sn—Al—Cu). The electrical connection metals 170 may have a single-layer structure or a multi-layer structure. For example, the multi-layer structure may include copper pillars and solders, and the single-layer structure may include tin silver solder or copper. The number, pitch, configuration, and the like of the electrical connection metals 170 are not limited.

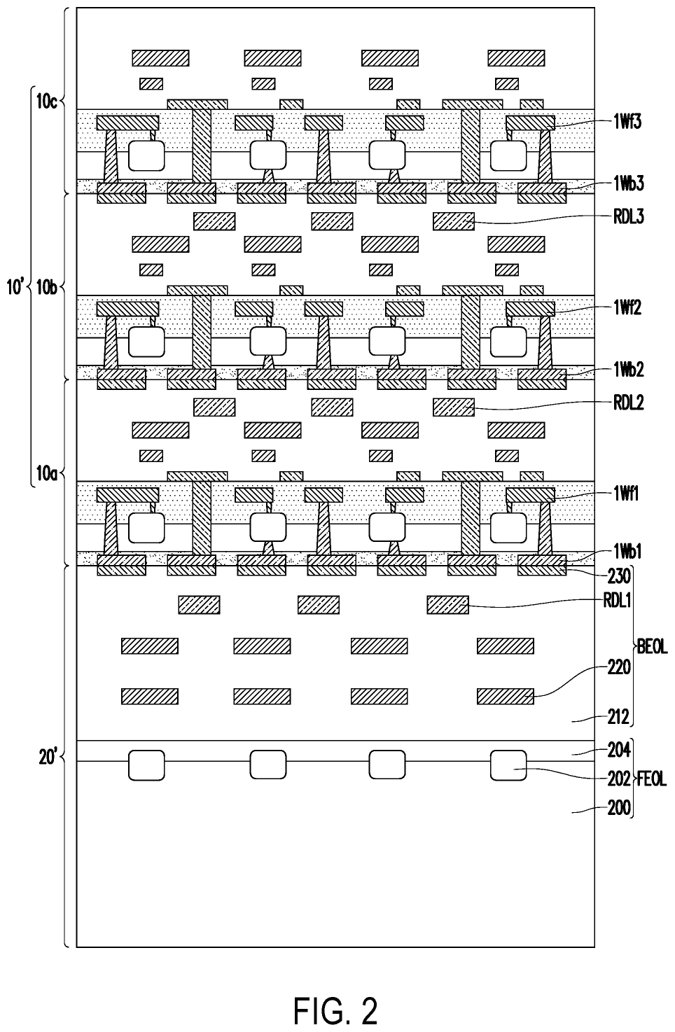

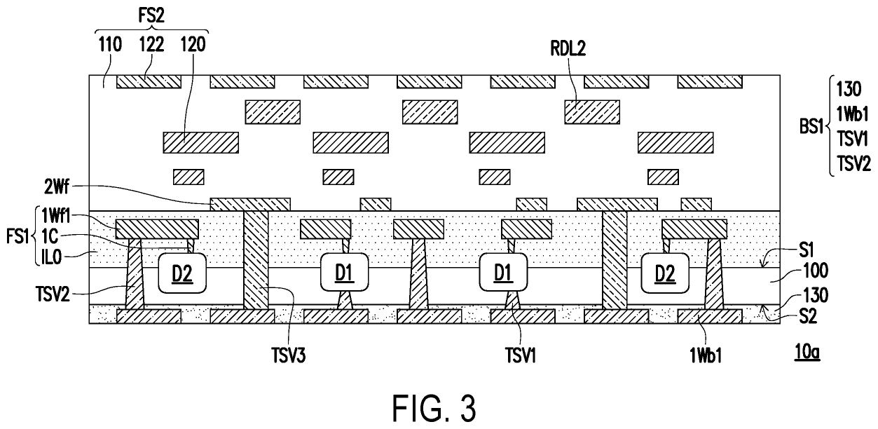

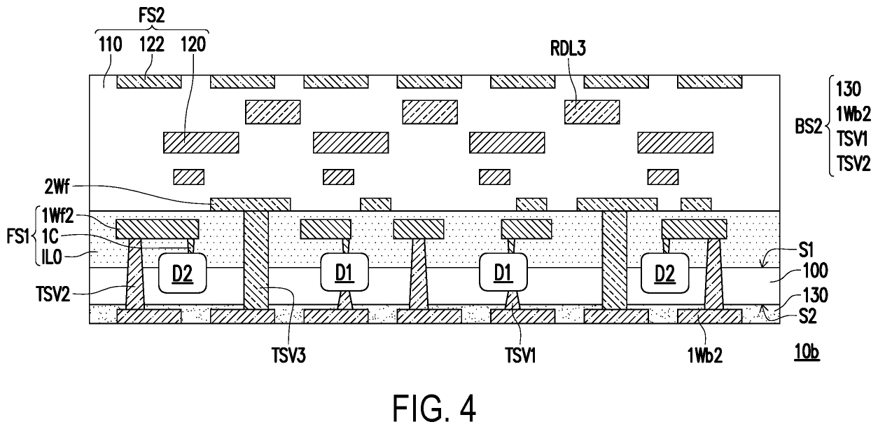

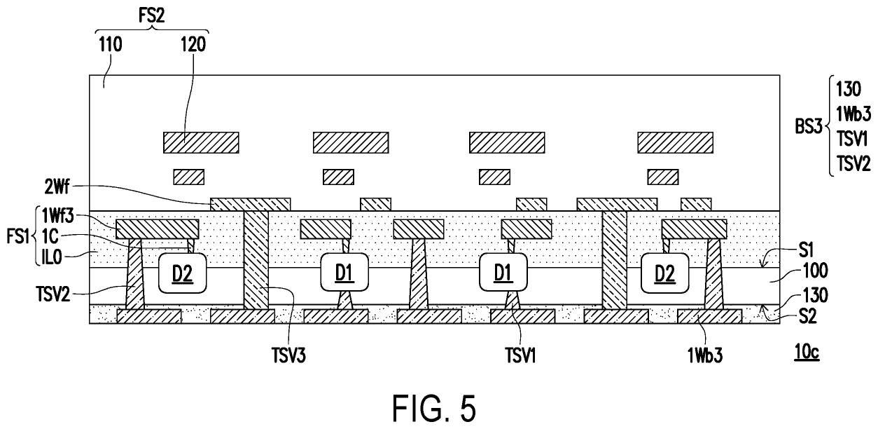

FIG. 2 is a schematic cross-section view illustrating a memory device of another embodiment of the invention. FIG. 3 is a schematic cross-section view illustrating a wafer 10a shown in FIG. 2 of an embodiment of the invention. FIG. 4 is a schematic cross-section view illustrating a wafer 10b shown in FIG. 2 of an embodiment of the invention. FIG. 5 is a schematic cross-section view illustrating a wafer 10c shown in FIG. 2 of an embodiment of the invention. The wafer stack 10′ shown in FIG. 2 includes a first wafer 10a, a second wafer 10b, and a third wafer 10c, wherein the first wafer 10a, the second wafer 10b, and the third wafer 10c are substantially similar to the wafer 10 shown in FIG. 1, so the same or similar components are represented by the same or similar reference numerals and will not be repeated hereinafter.

Referring to FIG. 2, the memory device includes a wafer stack 10′ and a carrier wafer 20′ carrying the wafer stack 10′. The wafer stack 10′ includes a first wafer 10a and a second wafer 10b stacked on the first wafer 10a. The memory device may include a dynamic random-access memory (DRAM).

Referring to FIG. 2 and FIG. 3, the first wafer 10a includes a first substrate 100, a first front interconnection structure FS1, a plurality of first elements (e.g., D1 and D2 shown in FIG. 3), a second front interconnection structure FS2, and a first rear interconnection structure BS1. The first substrate 100 includes a front surface S1 and a rear surface S2 opposite to each other. The first front interconnection structure FS1 is disposed on the front surface S1 of the first substrate 100. The first elements are disposed in the first substrate 100 and/or the first front interconnection structure FS1, wherein the first front interconnection structure FS1 includes a plurality of first wiring layers 1Wf1 configured to be closest to the first elements. The second front interconnection structure FS2 is disposed on the first front interconnection structure FS1. The first rear interconnection structure BS1 is disposed on the rear surface S2 of the first substrate 100 and includes a plurality of second wiring layers 1Wb1 configured to be closest to the first elements. Each of the first elements includes a first front electrical connection path through the first wiring layers 1Wf1 and a first rear electrical connection path through the second wiring layers 1Wb1.

Referring to FIG. 2 and FIG. 4, the second wafer 10b includes a second substrate 100, a third front interconnection structure FS1, a plurality of second elements (e.g., D1 and D2 shown in FIG. 4), a fourth front interconnection structure FS2, and a second rear interconnection structure BS2. The second substrate 100 is disposed on the second front interconnection structure FS2 and includes a front surface S1 and a rear surface S2 opposite to each other. The third front interconnection structure FS1 is disposed on the front surface S1 of the second substrate 100. The second elements are disposed in the second substrate 100 and/or the third front interconnection structure FS1, wherein the third front interconnection structure FS1 includes a plurality of third wiring layers 1Wf2 configured to be closest to the second elements. The fourth front interconnection structure FS2 is disposed on the third front interconnection structure FS1. The second rear interconnection structure BS2 is disposed on the rear surface S2 of the second substrate 100 and includes a plurality of fourth wiring layers 1Wb2 configured to be closest to the second elements. Each of the second elements includes a second front electrical connection path through the third wiring layers 1Wf2 and a second rear electrical connection path through the fourth wiring layers 1Wb2.

Referring to FIG. 2 to FIG. 4, the second front interconnection structure FS2 includes redistribution layers RDL2 connecting to the second rear electrical connection path (through the path of the fourth wiring layers 1Wb2). As such, the first elements (e.g., D1 or D2 shown in FIG. 3) of the first wafer 10a may be connected to the redistribution layers RDL2 through the first front electrical connection path (e.g., through the path of the first wiring layers 1Wf1), and the second elements (e.g., D1 or D2 shown in FIG. 4) of the second wafer 10b may be connected to the redistribution layers RDL2 through the second rear electrical connection path (e.g., through the path of the fourth wiring layers 1Wb2), and therefore the wafer stack 10′ is capable of achieving the design with more components by using the relaxed design rule, or is capable of achieving the design with the smaller horizontal area by using the relaxed design rule in the case where the wafer stack 10′ retains the number of the existing components. The redistribution layers RDL2 may include conductive materials such as metals or metal alloys. The metals and the metal alloys may be, for example, Cu, Al, Ti, Ta, W, Pt, Cr, Mo, or alloys thereof.

In some embodiments, as shown in FIG. 3 and FIG. 4, the first rear interconnection structure BS1 and the second rear interconnection structure BS2 may include first vias TSV1 respectively penetrating the first substrate 100 of the first wafer 10a and the second substrate 100 of the second wafer 10b and respectively contacting the first elements of the first wafer 10a and the second elements of the second wafer 10b.

In some embodiments, as shown in FIG. 3 and FIG. 4, each of the first rear interconnection structure BS1 and the second rear interconnection structure BS2 may include second vias TSV2, the second vias TSV2 of the first rear interconnection structure BS1 penetrate the first substrate 100 and the first front interconnection structure FS1 of the first wafer 10a and contact the first wiring layers 1Wf1, and the second vias TSV2 of the second rear interconnection structure BS2 penetrate the second substrate 100 and the third front interconnection structure FS1 of the second wafer 10b and contact the first wiring layers 1Wf1 and the third wiring layers 1Wf2.

In some embodiments, as shown in FIG. 3, the second front interconnection structure FS2 may include front pads 122 being in direct contact with the fourth wiring layers 1Wb2. That is, the first wafer 10a and the second wafer 10b can be bonded to each other by using a hybrid bond. For example, the front pads 122 of the first wafer 10a are in direct contact with the fourth wiring layers 1Wb2 of the second wafer 10b (i.e., metal-to-metal bonding), and the dielectric layer 110 of the first wafer 10a shown in FIG. 3 is in direct contact with the dielectric layer 130 of the second wafer 10b shown in FIG. 4 (i.e., dielectric-to-dielectric bonding).

In some embodiments, as shown in FIG. 4, the second wafer 10b may include through vias TSV3 penetrating through the third front interconnection structure FS1, the second substrate 100 and the second rear interconnection structure BS2, and the through vias TSV3 is in contact with one of the fourth wiring layers 1Wb2. In some embodiments, the through vias TSV3 electrically connect one of the fourth wiring layers 1Wb2 to the wiring layer 2Wf formed in the fourth front interconnection structure FS2. Namely, the second rear interconnection structure BS2 may be connected to the wiring layer 2Wf in the fourth front interconnection structure FS2 via the through vias TSV3 without being connected to the wiring layer 2Wf in the fourth front interconnection structure FS2 via the third front interconnection structure FS1. In some embodiments, the through vias TSV3 shown in FIG. 3 or FIG. 4 are formed after the first elements or the second elements are formed, so the through vias TSV3 may be regarded as TSV-middle.

As shown in FIG. 2, the carrier wafer 20′ may include a front-end process structure FEOL and a back-end process structure BEOL formed on the front-end process structure FEOL.

The front-end process structure FEOL may include a base substrate 200, a plurality of elements 202 and a device layer 204 where the elements 202 are formed therein. The base substrate 200 may include a semiconductor substrate or a SOI substrate. In some embodiments, the base substrate 200 may include materials identical to or similar to the materials of the substrate 100. The elements 202 may include active elements and/or passive elements. The device layer 204 may include elements (e.g., elements 202) formed therein and a dielectric layer covering the elements.

The back-end process structure BEOL may include a dielectric layer 212, interconnections 220 formed in the dielectric layer 212, front pads 230, and redistribution layers RDL1. In some embodiments, the redistribution layers RDL1 is connected to the first rear electrical connection path (e.g., through the path of the second wiring layers 1Wb1) of the first elements (e.g., D1 or D2 shown in FIG. 3) of the first wafer 10a. As such, the first elements (e.g., D1 or D2 shown in FIG. 3) of the first wafer 10a may be connected to the redistribution layers RDL1 through the first rear electrical connection path (e.g., through the path of the second wiring layers 1Wb1), so that the memory device is capable of achieving the design with more components by using the relaxed design rule, or is capable of achieving the design with the smaller horizontal area by using the relaxed design rule in the case where the memory device retains the number of the existing components.

The dielectric layer 212 may include a single dielectric layer or multiple dielectric layers, but the invention is not limited thereto. The dielectric layer 212 may include a dielectric material such an oxide (e.g., silicon oxide) or a nitride (e.g., silicon nitride). The interconnections 220 may include a single wiring layer or multiple wiring layers or redistribution layers and vias connecting the wiring layers or the redistribution layers. The interconnections 220 and/or the redistribution layers RDL1 may include conductive materials such as metals or metal alloys. The metals and the metal alloys may be, for example, Cu, Al, Ti, Ta, W, Pt, Cr, Mo, or alloys thereof.

The top surfaces of the front pads 230 may be exposed to a surface of the back-end process structure BEOL that faces the first wafer 10a, so that the carrier wafer 20′ and the first wafer 10a can be bonded to each other by using a hybrid bond. For example, the front pads 230 of the carrier wafer 20′ and the second wiring layers 1Wb1 of the first wafer 10a are in contact with each other (i.e., metal-to-metal bonding), and the dielectric layer 212 and the dielectric layer 130 are in contact with each other (i.e., dielectric-to-dielectric bonding).

In some embodiments, referring to FIG. 2, FIG. 4 and FIG. 5, the third wafer 10c is stacked on the second wafer 10b, wherein the second front interconnection structure FS2 of the second wafer 10b includes the redistribution layers RDL3 connected to the rear electrical connection path (e.g., the path through the wiring layer 1Wb3) of the third wafer 10c. As such, the elements (e.g., D1 or D2 shown in FIG. 4) of the second wafer 10b may be connected to the redistribution layers RDL3 through the front electrical connection path (e.g., the path through the wiring layer 1Wf2), and the elements (e.g., D1 or D2 shown in FIG. 5) of the third wafer 10c may be connected to the redistribution layers RDL3 through the rear electrical connection path (e.g., the path through the wiring layer 1Wb3), so that the wafer stack 10′ is capable of achieving the design with more components by using the relaxed design rule, or is capable of achieving the design with the smaller horizontal area by using the relaxed design rule in the case where the wafer stack 10′ retains the number of the existing components. The redistribution layers RDL3 may include conductive materials such as metals or metal alloys. The metals and the metal alloys may be, for example, Cu, Al, Ti, Ta, W, Pt, Cr, Mo, or alloys thereof.

From above, in the aforementioned memory device of the embodiments, the third interconnection structure including the second wiring layers is disposed on the rear side of the substrate, so that the first and the second elements not only include a first electrical connection path (through the first wiring layers) on the front side of the substrate but also include a second electrical connection path (through the second wiring layers) on the rear side of the substrate. Namely, some of wirings originally disposed in the wiring region on the front side of the wafer are moved to the rear side of the wafer, so the density of interconnections formed on the front side of the wafer can be reduced significantly. As such, in the case where the memory device retains the existing horizontal area, the memory device is capable of achieving the design with more components by using the relaxed design rule (e.g., the design including interconnections with high density and fine line widths are optional but not necessary).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device comprising:
a substrate comprising a first surface and a second surface opposite to each other;
a first interconnection structure disposed on the first surface of the substrate;
a first and a second elements disposed in the substrate and/or the first interconnection structure, wherein the first interconnection structure comprises a plurality of first wiring layers configured to be closest to the first and second elements;
a second interconnection structure disposed on the first interconnection structure; and
a third interconnection structure disposed on the second surface of the substrate and comprising a plurality of second wiring layers configured to be closest to the first and second elements,
wherein each of the first and second elements comprises a first electrical connection path through the first wiring layers and a second electrical connection path through the second wiring layers.

2. The memory device of claim 1, wherein the substrate comprises a cell region and a peripheral region adjacent to the cell region, and at least one of the first element and the second element is disposed in the peripheral region and is electrically connected to a memory array in the cell region through the first electrical connection path and/or the second electrical connection path.

3. The memory device of claim 2, wherein at least one of the first element and the second element comprises a sense amplifier or a word line driver.

4. The memory device of claim 3, wherein the first element is connected to the second element through the first electrical connection path and/or the second electrical connection path.

5. The memory device of claim 1, wherein the third interconnection structure comprises a first via penetrating the substrate and contacting the first element or the second element.

6. The memory device of claim 5, wherein the third interconnection structure comprises a second via penetrating the substrate and the first interconnection structure and contacting the first wiring layer.

7. A memory device comprising:
a first wafer comprising:
a first substrate comprising a front surface and a rear surface opposite to each other;
a first front interconnection structure disposed on the front surface of the first substrate;
a plurality of first elements disposed in the first substrate and/or the first front interconnection structure, wherein the first front interconnection structure comprises a plurality of first wiring layers configured to be closest to the first elements;
a second front interconnection structure disposed on the first front interconnection structure; and
a first rear interconnection structure disposed on the rear surface of the first substrate and comprising a plurality of second wiring layers configured to be closest to the first elements,
wherein each of the first elements comprises a first front electrical connection path through the first wiring layers and a first rear electrical connection path through the second wiring layers; and
a second wafer stacked on the first wafer and comprising:
a second substrate disposed on the second front interconnection structure and comprising a front surface and a rear surface opposite to each other;
a third front interconnection structure disposed on the front surface of the second substrate;
a plurality of second elements disposed in the second substrate and/or the third front interconnection structure, wherein the third front interconnection structure comprises a plurality of third wiring layers configured to be closest to the second elements;
a fourth front interconnection structure disposed on the third front interconnection structure; and
a second rear interconnection structure disposed on the rear surface of the second substrate and comprising a plurality of fourth wiring layers configured to be closest to the second elements,
wherein each of the second elements comprises a second front electrical connection path through the third wiring layers and a second rear electrical connection path through the fourth wiring layers, and
the second front interconnection structure comprises a redistribution layer connecting the second rear electrical connection path.

8. The memory device of claim 7, wherein the redistribution layer is connected to the first front electrical connection path.

9. The memory device of claim 7, wherein the first rear interconnection structure and the second rear interconnection structure comprise first vias respectively penetrating the first substrate and the second substrate and respectively contacting the first elements and the second elements.

10. The memory device of claim 9, wherein each of the first rear interconnection structure and the second rear interconnection structure comprises second vias, the second vias of the first rear interconnection structure penetrate the first substrate and the first front interconnection structure and contact the first wiring layers, and the second vias of the second rear interconnection structure penetrate the second substrate and the third front interconnection structure and contact the third wiring layers.

11. The memory device of claim 10, wherein the second front interconnection structure comprises front pads in direct contact with the fourth wiring layers.

12. The memory device of claim 11, wherein the second wafer comprises through vias penetrating through the third front interconnection structure, the second substrate, and the second rear interconnection structure and contacting one of the fourth wiring layers.
